(19) United States
(12) Patent Application Publication
(10) Pub. No.: US 2023/0028816 A1
(43) Pub. Date: Jan. 26, 2023

(54) FILM FORMING METHOD AND FILM FORMING SYSTEM

(71) Applicant: Tokyo Electron Limited, Tokyo (JP)

(72) Inventors: Zeyuan NI, Yamanashi (JP); Takashi MATSUMOTO, Yamanashi (JP); Ryota IFUKU, Yamanashi (JP)

(21) Appl. No.: 17/786,745

(22) PCT Filed: Dec. 17, 2020
(86) PCT No.: PCT/JP2020/047124

§ 371 Date: Jun. 17, 2022

(30) Foreign Application Priority Data
Dec. 24, 2019 (JP) 2019-233149

(51) Int. Cl. H01L 21/768; H01L 21/67; H01J 37/32; C23C 14/18; C23C 16/26

(52) U.S. Cl. CPC H01L 21/76846; C23C 14/18; C23C 16/26; H01J 37/32899; H01L 21/67167; H01L 21/76805; H01L 21/76895; H01J 2237/3321

(57) ABSTRACT

A film forming method includes: preparing a substrate that includes a base substrate and a first conductive film that is formed on the base substrate; forming, on the first conductive film, a composite layer that includes layers of graphene and includes, as dopant atoms, a transition metal from 4th period to 6th period in a periodic table, excluding lanthanoids, between the layers of graphene; and forming, on the composite layer, a second conductive film which is electrically connected to the first conductive film via the composite layer.

This is a National Phase Application filed under 35 U.S.C. 371 as a national stage of PCT/JP2020/047124, filed Dec. 17, 2020, an application claiming the benefit of Japanese Application No. 2019-233149, filed Dec. 24, 2019, the content of each of which is hereby incorporated by reference in its entirety.

### TECHNICAL FIELD

The present disclosure relates to a film forming method and a film forming system.

### BACKGROUND

Patent Document 1 discloses a technique for forming a graphene cap on the uppermost surface of a copper structure. When the graphene cap includes plural layers of graphene, the graphene cap may include dopant atoms or dopant molecules located between the layers of graphene or the top of the graphene layers.

### Prior Art Documents

### Patent Documents

Patent Document 1: Japanese Patent No. 6250037

An aspect of the present disclosure provides a technique capable of improving the longitudinal electric conductivity of a composite layer including graphene.

### SUMMARY

A film forming method of an aspect of the present disclosure includes preparing a substrate that includes a base substrate and a first conductive film that is formed on the base substrate, forming, on the first conductive film, a composite layer that includes layers of graphene and includes, as dopant atoms, a transition metal from 4th period to 6th period in periodic table , excluding lanthanoids, between the layers of graphene, and forming, on the composite layer, a second conductive film which is electrically connected to the first conductive film via the composite layer.

According to an aspect of the present disclosure, it is possible to improve the longitudinal electric conductivity of a composite layer including graphene.

### BRIEF DESCRIPTION OF DRAWINGS

FIG. 1 is a flowchart illustrating a film forming method according to an embodiment.

FIG. 2 is a flowchart illustrating an example of S2 of FIG. 1.

FIG. 3A is a cross-sectional view illustrating a first example of S1 of FIG. 1.

FIG. 3B is a cross-sectional view illustrating a first example of S21 of FIG. 2.

FIG. 3C is a cross-sectional view illustrating a first example of S22 of FIG. 2.

FIG. 3D is a cross-sectional view illustrating a first example of S23 of FIG. 2.

FIG. 3E is a cross-sectional view illustrating a first example of S3 of FIG. 1.

FIG. 4A is a cross-sectional view illustrating a second example of S1 of FIG. 1.

FIG. 4B is a cross-sectional view illustrating a second example of S2 of FIG. 1.

FIG. 4C is a cross-sectional view illustrating a second example of S3 of FIG. 1.

FIG. 4D is a cross-sectional view illustrating an example of a flattening process following FIG. 4C.

FIG. 5 is a view illustrating an example of a group of transition metals used in a composite layer.

FIG. 6A is a plan view illustrating an example of an AA type laminated structure.

FIG. 6B is a plan view illustrating an example of an AB type laminated structure.

FIG. 7A is a schematic view illustrating “atomic arrangement A” in Table 3.

FIG. 7B is a schematic view illustrating “atomic arrangement B” in Table 3.

FIG. 7C is a schematic view illustrating “atomic arrangement C” in Table 3.

FIG. 7D is a schematic view illustrating “atomic arrangement D” in Table 3.

FIG. 8 is a plan view illustrating a film forming system according to an embodiment.

FIG. 9 is a cross-sectional view illustrating an example of a first processing apparatus of FIG. 8.

FIG. 10 is a cross-sectional view illustrating an example of a second processing apparatus of FIG. 8.

FIG. 11 is a plan view illustrating an example of a B2B type laminated structure.

### DETAILED DESCRIPTION

Hereinafter, embodiments of the present disclosure will be described with reference to the drawings. In each drawing, the same or corresponding components may be denoted by the same reference numerals, and a description thereof may be omitted.

As described above, Patent Document 1 discloses a technique for forming a graphene cap on the uppermost surface of a copper structure. When the graphene cap includes plural layers of graphene, the graphene cap may include dopant atoms or dopant molecules located between the layers of graphene or the top of the graphene layers.

Graphene is formed by covalent bonds (sp2 bonds) of carbon atoms and has a honeycomb structure of carbon atoms. Graphene is a layer with the same thickness as one carbon atom. The electric conductivity of graphene is large in the horizontal direction (in-plane direction), but smaller in the vertical direction (thickness direction) than in the horizontal direction.

A composite layer including dopant atoms or dopant molecules between the layers of graphene are generally called a graphite intercalation compound (GIC). Patent Document 1 does not specifically describe dopant atoms and a dopant molecule.

Generally, an alkali metal such as potassium is used as the dopant atoms. In addition, a metal halide is used as the dopant molecule. The alkali metal or the metal halide contributes to the improvement of horizontal electric conductivity.

However, the vertical electric conductivity of the GIC in the related art was not sufficient.

In the present embodiment, as described later, a transition metal from the 4^{th} period to the 6^{th} period in a periodic table, excluding lanthanoids, is used as dopant atoms. As a result, π-electrons with strong delocalization and d-electrons with strong localization coexist, and both π-electrons and d-electrons interact in the vicinity of the Fermi level. Therefore, it is possible to improve the electric conductivity in the vertical direction of the GIC.

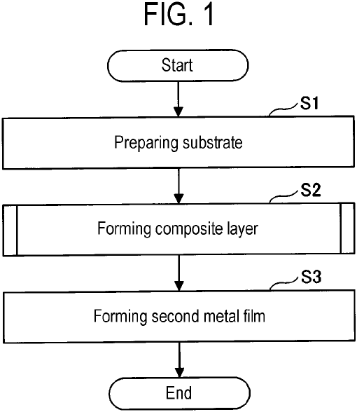

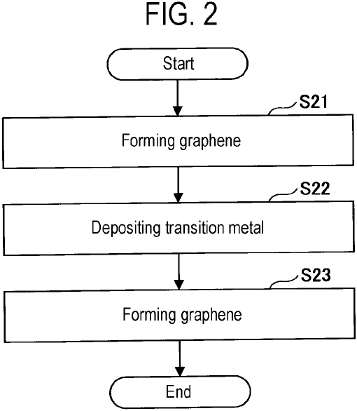

Hereinafter, a film forming method according to the present embodiment will be described with reference to FIG. 1 and the like. As illustrated in FIG. 1, the film forming method includes S1 to S3. As illustrated in FIG. 2, S2 in FIG. 1 includes S21 to S23. The order and number of graphene formation and transition metal deposition are not limited to the order and number of times illustrate in FIG. 2.

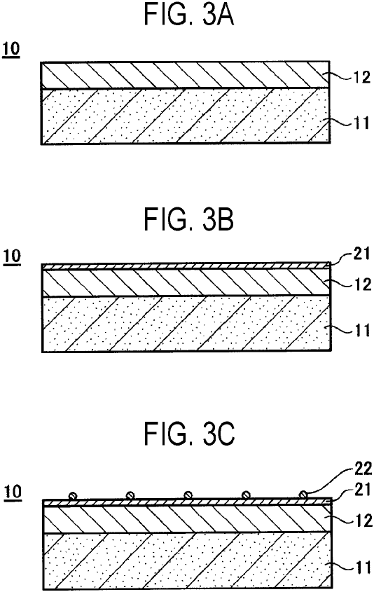

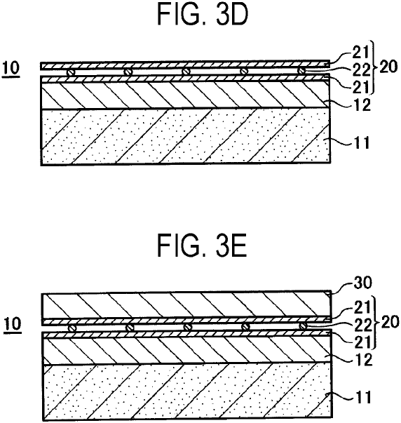

First, in S1 of FIG. 1, a substrate 10 is prepared as illustrated in FIG. 3A. The substrate 10 includes a base substrate 11 and a first conductive film 12 formed on the base substrate 11. The base substrate 11 is a semiconductor substrate such as a silicon wafer or a compound semiconductor substrate, or a glass substrate. The substrate 10 may further include an insulating film or the like between the base substrate 11 and the first conductive film 12.

The first conductive film 12 is a metal film containing Cu, W, Mo, Co, or Ru, or a semiconductor film containing a dopant. The metal film may be either a single metal film or an alloy film. The semiconductor film includes, for example, polycrystalline silicon or amorphous silicon. The dopant may be an n-type dopant such as phosphorus (P) or a p-type dopant such as boron (B).

Next, in S2 of FIG. 1, as illustrated in FIGS. 3B to 3D, a composite layer 20 is formed on the first conductive film 12. The composite layer 20 is a GIC and includes plural layers of graphene 21 and includes, between the layers of graphene 21, a transition metal 22 from the 4^{th} period to the 6^{th} period in a periodic table, excluding lanthanoids, as dopant atoms. S2 of FIG. 1 includes, for example, S21 to S23 in FIG. 2.

First, in S21 of FIG. 2, as illustrated in FIG. 3B, graphene 21 is formed in one or more layers and three or fewer layers. When the number of layers of graphene 21 is 3 or less, the thickness of the composite layer 20 is sufficiently thin, so the electric conductivity of the composite layer 20 in the vertical direction is sufficiently large. The graphene 21 formed in S21 is preferably a single layer. The graphene 21 is formed through, for example, a chemical vapor deposition (CVD) method.

The graphene 21 is formed through a plasma CVD method, a thermal CVD method, or the like. In the plasma CVD method, for example, microwaves are introduced into a processing container to generate a plasma of a carbon-containing gas, and the graphene 21 is formed by the plasma of the carbon-containing gas.

As the carbon-containing gas, for example, ethylene (C₂H₄), methane (CH₄), ethane (C₂H₆), propane (C₃H₈), propylene (C₃H₆), acetylene (C₂H₂), methanol (CH₃OH), ethanol (C₂H₅OH), or the like is used.

In the plasma CVD method, a hydrogen-containing gas may be introduced into the processing container together with the carbon-containing gas. The quality of graphene 21 can be improved. As the hydrogen-containing gas, for example, H₂ gas is used.

In the plasma CVD method, a rare gas is introduced into the processing container as a plasma generating gas. As the rare gas, Ar, He, Ne, Kr, Xe, or the like is used. Among these, Ar is preferable from the viewpoint of stably generating plasma.

An example of processing conditions of the plasma CVD method is shown below.
Flow rate of Ar gas: 0 sccm to 2,000 sccm
Flow rate of C₂H₄ gas: 0.1 sccm to 300 sccm
Flow rate of H₂ gas: 0.01 sccm to 500 sccm
Atmospheric pressure in the processing container: 1.33 Pa to 667 Pa (preferably 1.33 Pa to 400 Pa)
Temperature of substrate: 350° C. to 1,000° C. (preferably 400° C. to 800° C.)
Microwave power: 100 W to 5,000 W (preferably 1,000 W to 3,500 W)
Processing time: 1 min to 200 min.

In the thermal CVD method, a carbon-containing gas is thermally decomposed in the processing container to form the graphene 21. The carbon-containing gas used in the thermal CVD method is the same as the carbon-containing gas used in the plasma CVD method.

In the thermal CVD method, as in the plasma CVD method, a hydrogen-containing gas may be introduced into the processing container together with the carbon-containing gas. In the thermal CVD method, a rare gas may be introduced into the processing container as in the plasma CVD method. However, in the case of the thermal CVD method, the rare gas is not a plasma generating gas but a diluting gas.

An example of the processing conditions of the thermal CVD method is shown below.
Flow rate of Ar gas: 100 sccm to 2,000 sccm (preferably 300 sccm to 1,000 sccm)
Flow rate of C₂H₄ gas: 5 sccm to 200 sccm (preferably 6 sccm to 30 sccm)
Flow rate of H₂ gas: 100 sccm to 2,000 sccm (preferably 300 sccm to 1,000 sccm)
Atmospheric pressure in the processing container: 66.7 Pa to 667 Pa (preferably 400 Pa to 667 Pa)
Temperature of substrate: 300° C. to 600° C. (preferably 300° C. to 500° C.)
Processing time: 30 sec to 120 min (preferably 30 min to 90 min).

Next, in S22 of FIG. 2, as illustrated in FIG. 3C, a transition metal 22 is deposited on the graphene 21 as dopant atoms. The transition metal 22 is deposited through, for example, a physical vapor deposition (PVD) method.

The transition metal 22 is deposited through an ionized physical vapor deposition (iPVD) method, for example, a plasma sputtering method. An example of processing conditions of the plasma sputtering method is shown below.
Power supplied to IPC coil: 4 kW
DC power to target: 11 kW
RF bias applied to stage (13.56 MHz): 400 W
Atmospheric pressure in processing container: 12 Pa
Temperature of substrate: 300° C.

Next, in S23 of FIG. 2, as illustrated in FIG. 3D, graphene 21 is formed in one or more layers and three or fewer layers again. When the number of layers of graphene 21 is 3 or less, the thickness of the composite layer 20 is sufficiently thin, so the electric conductivity of the composite layer 20 in the vertical direction is sufficiently large. The graphene 21 formed in S23 is preferably a single layer. The graphene 21 is formed through the CVD method as described above.

As illustrated in FIG. 3D, the composite layer 20 alternately includes one or more layers and three or fewer layers of graphene 21 and the transition metal 22. The total number of layers of graphene 21 is 2 or more and 10 or less, preferably 2 or more and 5 or less. The smaller the total number of layers of graphene 21, the higher the electric conductivity of the composite layer 20 in the vertical direction.

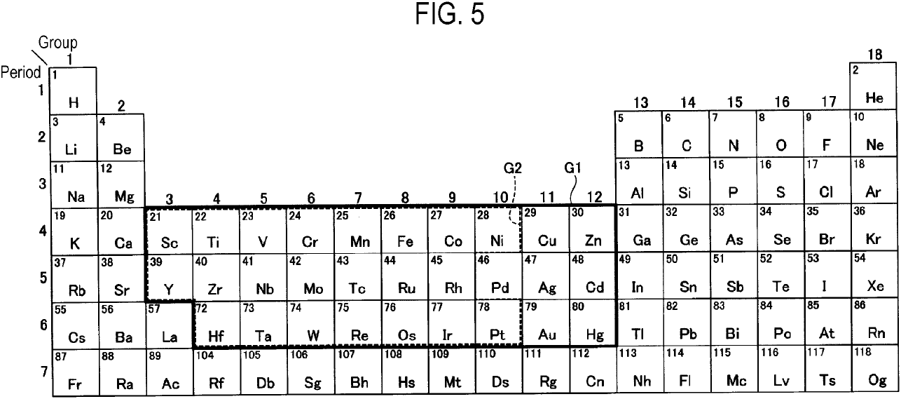

The transition metal 22 is selected from a first group G1 illustrated in FIG. 5. The first group G1 is composed of transition metals from the 4^{th} period to the 6^{th} period in periodic table excluding lanthanoids. The transition metals belonging to the first group G1 are Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, and Hg.

Since the composite layer 20 includes the transition metal 22 belonging to the first group G1 as dopant atoms, as described above, π electrons with strong delocalization and d electrons with strong localization coexist, and both the π electrons and the d electrons interact with each other near the Fermi level. Therefore, it is possible to improve the electric conductivity in the vertical direction of the composite layer 20.

The composite layer 20 may be selected from a second group G2 illustrated in FIG. 5. The second group G2 is composed of transition metals having an open-shell d-orbital and having 1 or more and 9 or less d-electrons in the open-shell d-orbital. The open-shell d-orbital of the 4^{th} period is 3d, the open-shell d-orbital of the 5^{th} period is 4d, and the open-shell d-orbital of the 6^{th} period is 5d. The transition metals belonging to the second group G2 are Sc, Ti, V, Cr, Mn, Fe, Co, Ni, Y, Zr, Nb, Mo, Tc, Ru, Rh, Hf, Ta, W, Re, Os, Ir, and Pt.

When the composite layer 20 includes the transition metal 22 belonging to the second group G2 as dopant atoms, the interaction between the π electron and the d electron near the Fermi level is activated. Therefore, it is possible to further improve the electric conductivity in the vertical direction of the composite layer 20.

When the composite layer 20 includes Ti as the transition metal 22, the interaction between the transition metal 22 and the graphene 21 is strong, so that a stable structure is obtained, and it is easier to obtain the “AA” structure to be described later than the “AB” structure to be described later. The “AA” structure has a higher electric conductivity than the “AB” structure. Therefore, when the composite layer 20 includes Ti as the transition metal 22, it is possible to further improve the electric conductivity in the vertical direction of the composite layer 20.

Table 1 shows the electric conductivities in the vertical direction of GIC or the like in which the monatomic layers of graphene 21 and the monatomic layers of the transition metal 22 are alternately laminated. The electric conductivity in the vertical direction is also simply referred to as electric conductivity below. The electric conductivities of GIC and graphene shown in Table 1 were determined by a density functional theory (DFT) and a non-equilibrium Green’s function (NEGF) method. The electric conductivities of the Cu and TiN produced through a PVD method shown in Table 1 are actually measured values.

Table 1

| | | |
|---|---|---|
| | Laminated structure of graphene | Vertical electric conductivity (S/m) |
| Ti-containing GIC | AA | 8.73×10⁵ |
| Cu-containing GIC | AB | 5.84×10⁵ |
| Cu-containing GIC | AA | 4.29×10⁵ |
| Graphene | AB | 7.47×10⁴ |
| Graphene | | 3.33×10³ |
| Cu | | 5.96×10⁷ |
| PVD TiN | | 1×10¹ ∼ 3×10² |

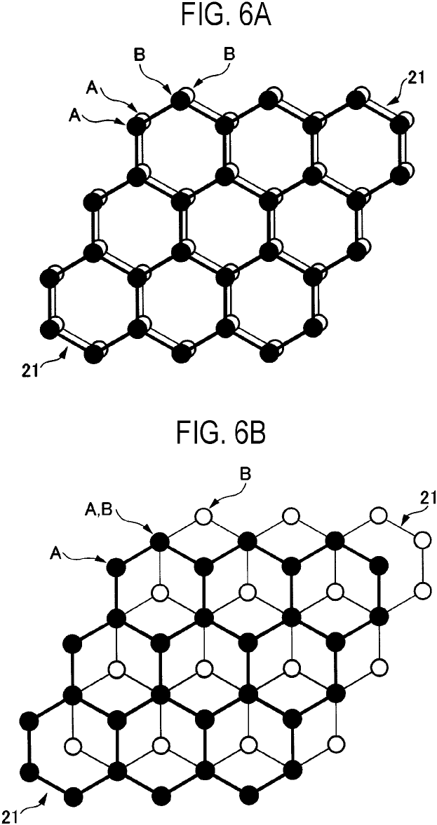

In Table 1, “AA” and “AB” indicate laminated structures of graphene 21. As illustrated in FIG. 6A, “AA” is a laminated structure in which, of two carbon atoms A and B in each unit cell of graphene 21, an atom A is arranged directly above the atom A and an atom B is arranged directly above the atom B. As illustrated in FIG. 6B, “AB” is a laminated structure in which, of two carbon atoms A and B in each unit cell of graphene 21, a carbon atom is arranged directly above the atom A, but no carbon atom is arranged directly above the atom B.

From Table 1, the following (1) to (3) are clear. (1) Since the composite layer 20, which includes the transition metal 22 as dopant atoms between the layers of graphene 21, the composite layer 20 has a higher electric conductivity than the graphene 21. (2) When transition metals 22 are the same, “AA” has a higher electric conductivity than “AB”. (3) “Ti” is capable of further improving the electric conductivity of GIC compared with “Cu”.

The composite layer 20 may take either “AA” or “AB” as the laminated structure of graphene 21. However, the Ti-containing GIC is more likely to take “AA” having a high electric conductivity than “AB” having a low electric conductivity as the laminated structure of graphene 21. The Cu-containing GIC takes, as the laminated structure of graphene 21, “AB” having a low electric conductivity and “AA” having a high electric conductivity to the same extent. Therefore, it is considered that the difference in electric conductivity between actual Ti-containing GIC and Cu-containing GIC is larger than the difference in electric conductivity between the Ti-containing GIC of “AA” and the Cu-containing GIC of “AA”.

Table 2 shows the electric conductivities of GIC in which the monatomic layers of graphene 21 and the monatomic layers of transition metal 22 are alternately laminated. The electric conductivities shown in Table 2 were determined by the density functional theory and the non-equilibrium Green’s function method. The most stable laminated structure, the most stable lattice constant c, and the most stable spin arrangement were adopted for each element of the transition metals 22.

Table 2

| Transition metal | Laminated structure of graphene | Lattice Constant C(Å) | Spin arrangement (magnetic) | Vertical electric conductivity (S/m) |
|---|---|---|---|---|
| V | AA | 7.0 | FM | 1.03×10⁶ |
| Rh | B2B | 8.6 | NM | 1.00×10⁶ |
| Ti | AA | 7.4 | FM | 8.73×10⁵ |
| Mo | AB | 7.0 | NM | 8.53×10⁵ |
| W | AB | 7.0 | NM | 8.26×10⁵ |
| Zn | B2B | 9.6 | NM | 6.21×10⁵ |
| Zr | B2B | 7.6 | NM | 5.69×10⁵ |
| Nb | AB | 7.4 | NM | 5.03×10⁵ |
| Mn | B2B | 8.6 | FM | 4.73×10⁵ |
| Hf | B2B | 7.4 | NM | 4.51×10⁵ |
| Cu | B2B | 8.2 | NM | 4.29×10⁵ |
| Co | B2B | 6.8 | FM | 3.92×10⁵ |
| Ru | AB | 7.4 | NM | 3.75×10⁵ |
| Cr | B2B | 8.6 | FM | 1.90×10⁵ |

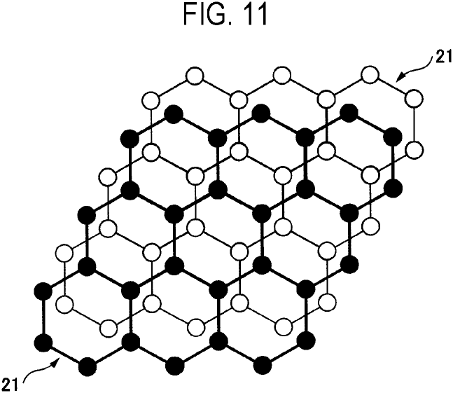

In Table 2, “AA”, “AB”, and “B2B” indicate the laminated structures of graphene 21. “AA” is the laminated structure illustrated in FIG. 6A, “AB” is the laminated structure illustrated in FIG. 6B, and “B2B” is the laminated structure illustrated in FIG. 11. In addition, in Table 2, “FM” means a ferromagnetic spin arrangement, and “NM” means a non-magnetic spin arrangement.

From Table 2, it can be seen that V, Rh, Ti, Mo, and W are capable of further improving the electric conductivity of GIC compared with other transition metals.

As described above, the composite layer 20 of the present embodiment is formed by alternately repeating the formation of graphene 21 and the deposition of the transition metal 22, but the technique of the present disclosure is not limited thereto. For example, after the formation of all graphene 21, the transition metal 22 may be deposited, then heat treatment may be performed, and the transition metal 22 may be inserted between the layers of graphene 21 through thermal diffusion. In addition, after the transition metal 22 is deposited, all the graphene 21 may be formed, then heat treatment may be performed, and the transition metal 22 may be inserted between the layers of graphene 21 through thermal diffusion. However, from the viewpoint of suppressing the thermal decomposition of graphene 21, it is preferable to alternately repeat the formation of graphene 21 and the deposition of the transition metal 22. The composite layer 20 may also be formed by, after forming a multilayer film of the graphene 21, inserting a halide of the transition metal 22 between the layers of graphene 21 and reducing the inserted halide with a reducing gas. The composite layer 20 includes, between layers of graphene 21, the transition metal 22 as dopant atoms.

Next, in S3 of FIG. 1, as illustrated in FIG. 3E, a second conductive film 30 electrically connected to the first conductive film 12 via the composite layer 20 is formed on the composite layer 20. The second conductive film 30 is formed through a CVD method, a PVD method, a plating method, or the like.

The second conductive film 30 is a metal film including Cu, W, Mo, Co, or Ru, or a semiconductor film including a dopant, similarly to the first conductive film 12. The metal film may be either a single metal film or an alloy film. The semiconductor film includes, for example, polycrystalline silicon or amorphous silicon. The dopant may be an n-type dopant such as phosphorus (P) or a p-type dopant such as boron (B).

As illustrated in FIG. 3E, the composite layer 20 is formed between the first conductive film 12 and the second conductive film 30. The composite layer 20 is formed for the purpose of preventing the diffusion of a metal or the diffusion of a semiconductor dopant, and has a function as a barrier layer. As is clear from Table 1, it is possible to improve the vertical electric conductivity compared with the case in which TiN or the like is used as the barrier layer.

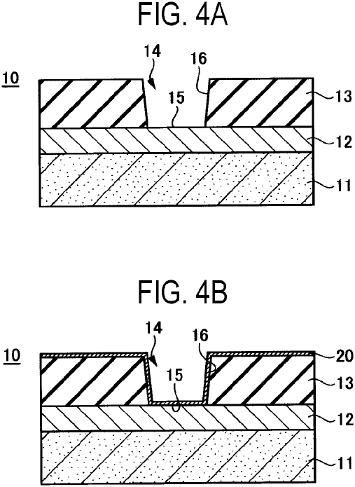

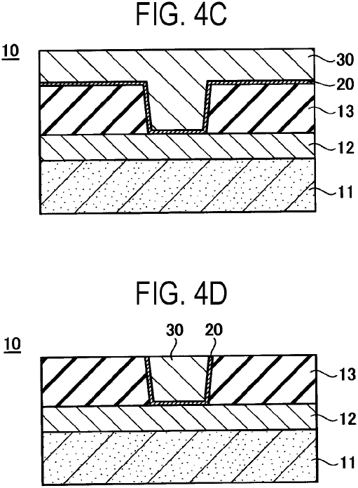

Next, with reference to FIG. 4, a case in which the composite layer 20 is a barrier layer for preventing the diffusion of a metal will be described.

First, in S1 of FIG. 1, a substrate 10 is prepared as illustrated in FIG. 4A. In addition to the base substrate 11 and the first conductive film 12, the substrate 10 includes an insulating film 13 formed on the first conductive film 12 and a recess 14 that penetrates the insulating film 13 and exposes the first conductive film 12.

The insulating film 13 is an interlayer insulating film. The material of the insulating film 13 is, for example, a metal compound. The metal compound is aluminum oxide, silicon oxide, silicon nitride, silicon oxynitride, silicon oxycarbide, silicon carbide, or the like. The material of the insulating film 13 may be a low dielectric constant material (Low-k material) having a dielectric constant lower than that of SiO₂.

The recess 14 is a contact hole, a trench, a via hole, or the like.

Next, in S2 of FIG. 1, as illustrated in FIG. 4B, a composite layer 20 is formed on the bottom surface 15 and the side surfaces 16 of the recess 14. As described above, the composite layer 20 is formed by alternately repeating the formation of graphene 21 and the deposition of transition metal 22. The composite layer 20 may be formed through heat diffusion as described above.

Next, in S3 of FIG. 1, the recess 14 is filled with a second conductive film 30 as illustrated in FIG. 4C. Then, as illustrated in FIG. 4D, an extra second conductive film 30 and an extra composite layer 20 are removed through Chemical Mechanical Polishing (CMP) or the like such that the surface of the insulating film 13 is exposed.

As illustrated in FIG. 4D, the composite layer 20 is formed between the first conductive film 12 and the second conductive film 30. The composite layer 20 is a barrier layer that prevents the diffusion of a metal from the second conductive film 30 to the insulating film 13. As is clear from Table 1, it is possible to improve the vertical electric conductivity compared with the case in which TiN or the like is used as the barrier layer.

The composite layer 20 may be formed between the first conductive film 12 and the insulating film 13, or may prevent the metal from diffusing from the first conductive film 12 to the insulating film 13.

As described above, the composite layer 20 may be intended to prevent the diffusion of a semiconductor dopant. For example, when the first conductive film 12 is a semiconductor film including a dopant and the second conductive film 30 is a metal film, the composite layer 20 prevents the dopant from diffusing from the first conductive film 12 to the second conductive film 30. When the first conductive film 12 is a metal film and the second conductive film 30 is a semiconductor film including a dopant, the composite layer 20 prevents the dopant from diffusing from the second conductive film 30 to the first conductive film 12.

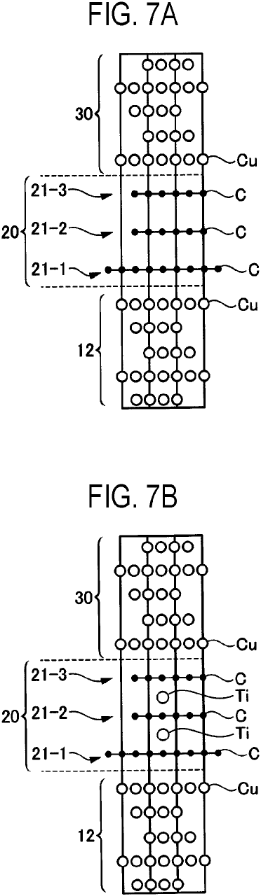

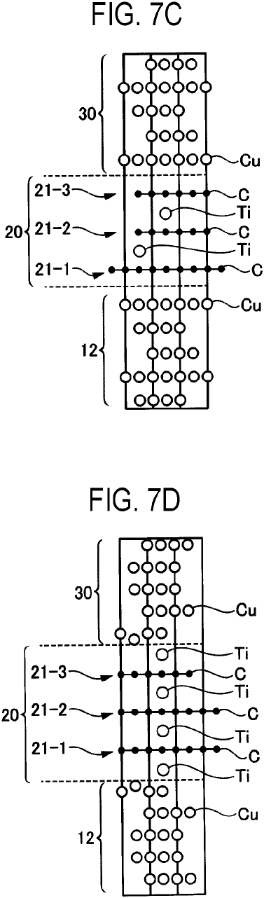

Next, with reference to FIG. 7 and Table 3, the relationship between the atomic arrangement of the composite layer 20 and the vertical electric conductivity between the first conductive film 12 and the second conductive film 30 via the composite layer 20 will be described. The electric conductivities shown in Table 3 are values when the material of the first conductive film 12 and the second conductive film 30 is Cu, the laminated structure of graphene 21 is “AA”, and the transition metal 22 is Ti. The electric conductivities illustrated in Table 3 were determined by the density functional theory and the non-equilibrium Green’s function method.

Table 3

| | | | |
|---|---|---|---|
| | Drawing | FM/AFM | Vertical electric conductivity (S/m) |
| Atomic arrangement A | FIG. 7A | | 9.91×10¹ |
| Atomic arrangement B | FIG. 7B | FM | 1.92×10⁴ |
| | | AFM | 1.12×10⁴ |
| Atomic arrangement C | FIG. 7C | FM | 2.91×10⁴ |
| | | AFM | 2.77×10⁴ |
| Atomic arrangement D | FIG. 7D | FM | 2.81×10⁵ |

In Table 3, “FM” means a ferromagnetic spin arrangement and “AFM” means an antiferromagnetic spin arrangement.

As illustrated in FIG. 7A, the composite layer 20 of “atomic arrangement A” includes only three layers of graphene 21-1, 21-2, and 21-3, and no Ti atom is included between these layers of graphene 21-1, 21-2, and 21-3.

As illustrated in FIG. 7B, the composite layer 20 of “atomic arrangement B” includes three layers of graphene 21-1, 21-2, and 21-3, and further, Ti atoms are included between these layers of graphene 21-1, 21-2, and 21-3. Directly above one Ti atom, another Ti atom is arranged.

As illustrated in FIG. 7C, the composite layer 20 of “atomic arrangement C” includes three layers of graphene 21-1, 21-2, and 21-3, and further, Ti atoms are included between these layers of graphene 21-1, 21-2, and 21-3. Directly above one Ti atom, another Ti atom is not arranged. Another Ti atom is arranged to be shifted in lateral direction.

As illustrated in FIG. 7D, the composite layer 20 of the “atomic arrangement D” includes not only Ti atoms between the layers of graphene 21 but also Ti atoms on the top and bottom surfaces thereof. The composite layer 20 of the “atomic arrangement D” includes Ti atoms between the graphene 21-1 closest to the first conductive film 12 and the first conductive film 12. In addition, the composite layer 20 of the “atomic arrangement D” includes Ti atoms between the graphene 21-3 closest to the second conductive film 30 and the second conductive film 30. Directly above one Ti atom, other three Ti atoms are arranged in a row.

From Table 3, the following (1) and (2) are clear. (1) Since the composite layer 20 includes Ti atoms as dopant atoms between the layers of graphene 21, it is possible to improve the electric conductivity in the vertical direction by about 100 times compared with the case in which the composite layer 20 does not include Ti atoms. (2) Since the composite layer 20 includes Ti atoms not only between the layers of graphene 21, but also on the top and bottom surfaces thereof, it is possible to improve the electric conductivity in the vertical direction by about 10 times compared with the case in which Ti atoms are not included on the top and bottom surfaces. Since the Ti atoms and the Cu atoms are adjacent to each other, it is considered that the electric conductivity is improved by the interaction between the Ti atoms and the Cu atoms.

The composite layer 20 illustrated in FIG. 7D may include Ti atoms in a space between graphene 21-1 closest to the first conductive film 12 and the first conductive film 12 and in a space between the graphene 21-3 closest to the second conductive film 30 and the second conductive film 30, but may include Ti atoms in only one of the spaces. In the latter case as well, the electric conductivity can be further improved by the interaction between the Ti atoms and the Cu atoms.

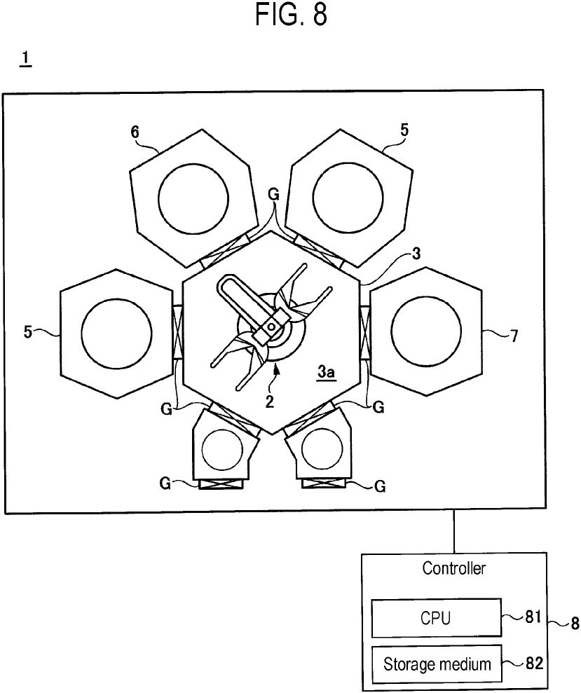

Next, with reference to FIG. 8, a film forming system 1 that executes the film forming method shown in FIG. 1 will be described. The film forming system 1 is a so-called multi-chamber system, and as illustrated in FIG. 8, includes a transport apparatus 2, an interface apparatus 3, a first processing apparatus 5, a second processing apparatus 6, a third processing apparatus 7, and a controller 8.

The transport apparatus 2 transports a substrate 10. The interface apparatus 3 forms a vacuum chamber 3a for accommodating the transport apparatus 2. The vacuum chamber 3a is evacuated by a vacuum pump and is maintained at a preset degree of vacuum. In the vacuum chamber 3a, the transport apparatus 2 is disposed to be movable in the vertical and horizontal directions and to be rotatable around the vertical axis. The transport apparatus 2 transports the substrate 10 to the first processing apparatus 5 and the second processing apparatus 6.

The first processing apparatus 5 is located adjacent to the interface apparatus 3 and forms one or more layers and three or fewer layers of graphene 21 on the first conductive film 12. The second processing apparatus 6 is located adjacent to the interface apparatus 3 and deposits a transition metal 22 as dopant atoms on the graphene 21. The number and arrangement of first processing apparatuses 5 and the number and arrangement of second processing apparatuses 6 are not limited to the number and arrangement illustrated in FIG. 8.

The transport apparatus 2 also transports the substrate 10 to the third processing apparatus 7. The third processing apparatus 7 is located adjacent to the interface apparatus 3 and forms, on the composite layer 20, a second conductive film 30 electrically connected to the first conductive film 12 via the composite layer 20.

The controller 8 is configured with, for example, a computer, and includes a central processing unit (CPU) 81 and a non-transient computer readable storage medium 82, such as a memory. The storage medium 82 stores a program for controlling various processes executed in the film forming system 1. The controller 8 controls the operation of the film forming system 1 by causing the CPU 81 to execute the program stored in the storage medium 82.

The controller 8 controls the transport apparatus 2, the first processing apparatus 5, and the second processing apparatus 6, and alternately repeats the formation of graphene 21 and the deposition of the transition metal 22 to form the composite layer 20. The formation of the composite layer 20 may be executed through heat diffusion, and for example, the first processing apparatus 5 may execute the formation and heat diffusion of graphene 21.

In addition, the controller 8 also controls the third processing apparatus 7 to form the second conductive film 30. The formation of the second conductive film 30 may be performed outside the film forming system 1, and the film forming system 1 may not be provided with the third processing apparatus 7.

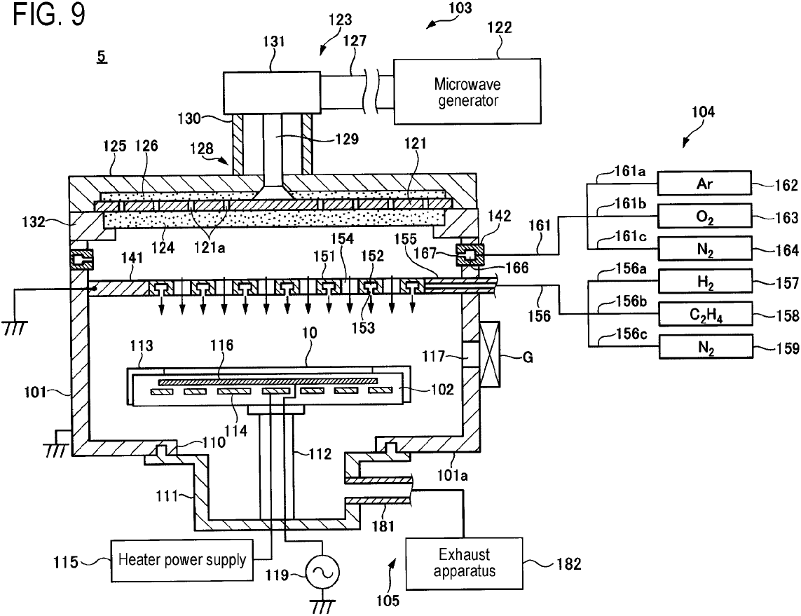

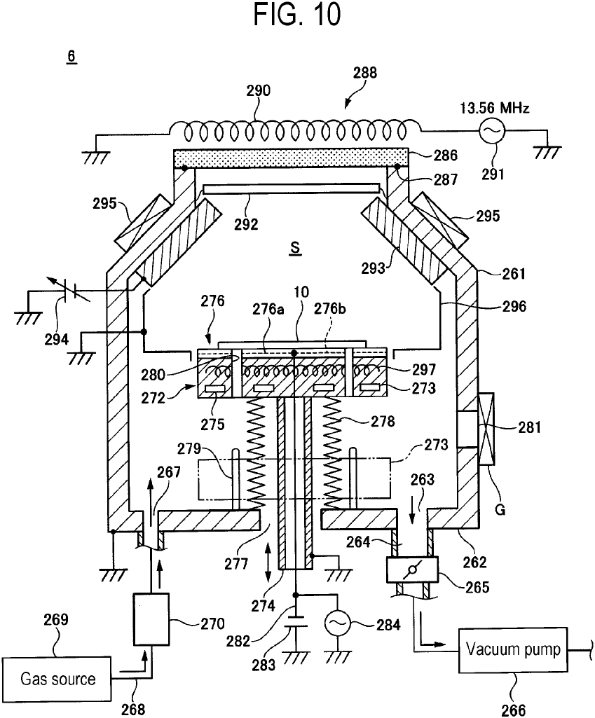

Next, the first processing apparatus 5 will be described with reference to FIG. 9. The first processing apparatus 5 illustrated in FIG. 9 is a plasma CVD apparatus, but may also be used as a thermal CVD apparatus. The first processing apparatus 5 includes a substantially cylindrical processing container 101, a stage 102 provided in the processing container 101 so that the substrate 10 is placed on the stage 102, a microwave introduction mechanism 103 configured to introduce microwaves into the processing container 101, a gas supply mechanism 104 configured to guide gas into the processing container 101, and an exhauster 105 configured to evacuate the interior of the processing container 101.

The processing container 101 includes a circular opening 110 in a substantially central portion of the bottom wall 101a. The bottom wall 101a is provided with an exhaust chamber 111 that communicates with the opening 110 and protrudes downward. On the side wall of the processing container 101, a carry-in/out port 117 for the substrate 10 by the transport apparatus 2 illustrated in FIG. 8 and a gate valve G configured to open/close the carry-in/out port 117 are provided.

The stage 102 has a disk shape and is made of ceramic, such as A1N. The stage 102 is supported by a cylindrical support member 112 made of ceramic such as A1N extending upward from the center of the bottom portion of the exhaust chamber 111. A guide ring 113 for guiding the substrate 10 is provided on the outer edge of the stage 102. Inside the stage 102, lifting pins (not illustrated) for raising and lowering the substrate 10 are provided to be capable of protruding and retracting with respect to the top surface of the stage 102. A resistance heating type heater 114 is embedded inside the stage 102. The heater 114 heats the substrate 10 on the stage 102 via the stage 102 by being fed with power from a heater power supply 115. In addition, a thermocouple (not illustrated) is inserted into the stage 102, and the controller 8 controls the heating temperature of the substrate 10 based on a signal from the thermocouple. Above the heater 114 in the stage 102, an electrode 116 having the same size as the substrate 10 is embedded. A radio-frequency bias power supply 119 is electrically connected to the electrode 116. Radio-frequency bias for drawing in ions is applied from the radio-frequency bias power supply 119 to the stage 102. The radio-frequency bias power supply 119 may not be provided depending on the characteristics of plasma processing.

The microwave introduction mechanism 103 includes a planar slot antenna 121 provided to face the opening in the top portion of the processing container 101 and provided with a large number of slots 121a, a microwave generator 122 configured to generate microwaves, and a microwave transmission mechanism 123 configured to guide the microwaves from the microwave generator 122 to the planar slot antenna 121. Below the planar slot antenna 121, a microwave transmission plate 124 made of a dielectric material is provided to be supported by an upper plate 132 provided in a ring shape in the upper portion of the processing container 101, and a shield member 125 having a water-cooled structure is provided above the planar slot antenna 121. In addition, a slow-wave material 126 is provided between the shield member 125 and the planar slot antenna 121.

The planar slot antenna 121 is made of, for example, a copper plate or an aluminum plate having a silver or gold-plated surface, and has a configuration in which the plural slots 121a for radiating microwaves are formed through the plate in a desired pattern. The pattern of the slots 121a is appropriately set such that the microwaves are evenly radiated. An example of a suitable pattern includes a radial line slot in which the two slots 121a configuring one pair are arranged in a T shape, and plural pairs of slots 121a are arranged in a concentric circle shape. The lengths and the arrangement intervals of the slots 121a are appropriately determined according to the effective wavelength λg of microwaves. The slots 121a may have other shapes such as a circular shape and an arc shape. The arrangement form of the slots 121a is not particularly limited, and the slots 121a may be arranged, for example, in a spiral shape or a radial shape, in addition to the concentric circle shape. The pattern of the slots 121a is appropriately set to have a microwave radiation characteristic that is capable of obtaining a desired plasma density distribution.

The slow-wave material 126 is made of a dielectric material having a dielectric constant greater than that of a vacuum, for example, quartz, ceramic (Al₂O₃), or a resin such as polytetrafluoroethylene or polyimide. The slow-wave material 126 functions to make the wavelength of the microwaves shorter than that in a vacuum, thereby reducing the size of the planar slot antenna 121. The microwave transmission plate 124 is also made of the same dielectric material.

The thicknesses of the microwave transmission plate 124 and the slow-wave material 126 are adjusted such that an equivalent circuit formed by the slow-wave material 126, the planar slot antenna 121, the microwave transmission plate 124, and the plasma satisfies resonance conditions. By adjusting the thickness of the slow-wave material 126, the phase of the microwaves can be adjusted, and by adjusting the thickness of the planar slot antenna 121 such that the joint portion of the planar slot antenna 121 becomes a “loop” of a standing wave, the reflection of microwaves is minimized and the radiant energy of microwaves is maximized. In addition, when the slow-wave material 126 and the microwave transmission plate 124 are made of the same material, it is possible to prevent the interface reflection of microwaves.

The microwave generator 122 includes a microwave oscillator. The microwave oscillator may be a magnetron oscillator or a solid-state oscillator. The frequency of microwaves oscillated from the microwave oscillator may be in the range of 300 MHz to 10 GHz. For example, by using the magnetron as the microwave oscillator, it is possible to oscillate microwaves having a frequency of 2.45 GHz.

The microwave transmission mechanism 123 includes a waveguide 127 extending in the horizontal direction for guiding microwaves from the microwave generator 122, a coaxial waveguide 128 including an inner conductor 129 extending upward from the center of the planar slot antenna 121 and an outer conductor 130 outside the inner conductor 129, and a mode conversion mechanism 131 provided between the waveguide 127 and the coaxial waveguide 128. The microwaves generated by the microwave generator 122 propagate in the waveguide 127 in the transverse electric (TE) mode, the vibration mode of the microwaves is converted from the TE mode to the transverse electromagnetic (TEM) mode by the mode conversion mechanism 131, and the microwaves are guided to the slow-wave material 126 through the coaxial waveguide 128 to be radiated from the slow-wave material 126 into the processing container 101 via the slots 121a of the planar slot antenna 121 and the microwave transmission plate 124. A tuner (not illustrated) configured to match the impedance of a load (plasma) in the processing container 101 with the characteristic impedance of the power supply of the microwave generator 122 is provided in the middle of the waveguide 127.

The gas supply mechanism 104 includes a shower plate 141 horizontally provided above the stage in the processing container 101 to partition the upper and lower portions of the interior of the processing container 101, and a shower ring 142 provided above the shower plate 141 in a ring shape along the inner wall of the processing container 101.

The shower plate 141 includes grid-shaped gas flow members 151, grid-shaped gas flow paths 152 provided inside the gas flow members 151, respectively, and a large number of gas ejection holes 153 extending downward from the gas flow paths 152, respectively, and through holes 154 are provided between the grid-shaped gas flow members 151. A gas supply path 155 reaching the outer wall of the processing container 101 extends in the gas flow paths 152 of the shower plate 141, and a gas supply pipe 156 is connected to the gas supply path 155. The gas supply pipe 156 is branched into three branch pipes 156a, 156b, and 156c. The H₂ gas source 157 configured to supply H₂ gas as a reducing gas, a C₂H₄ gas source 158 configured to supply C₂H₄ gas as a carbon-containing gas, and a N₂ gas source 159 configured to supply N₂ gas used as a purging gas or the like are connected these branch pipes 156a, 156b, and 156c, respectively. Although not illustrated, each of the branch pipes 156a, 156b, and 156c is provided with a mass flow controller for controlling a flow rate and valves before and after the mass flow controller.

The shower ring 142 includes a ring-shaped gas flow path 166 provided therein and a large number of gas ejection holes 167 connected to the gas flow path 166 and opened to the inner side of the shower ring 142. A gas supply pipe 161 is connected to the gas flow path 166. The gas supply pipe 161 is branched into three branch pipes 161a, 161b, and 161c. An Ar gas source 162 configured to supply Ar gas as a rare gas, an O₂ gas source 163 configured to supply O₂ gas as an oxidizing gas that is a cleaning gas, and a N₂ gas source 164 configured to supply N₂ gas used as a purging gas or the like are connected to the branch pipes 161a, 161b, and 161c, respectively. Although not illustrated, each of the branch pipes 161a, 161b, and 161c is provided with a mass flow controller for controlling a flow rate and valves before and after the mass flow controller.

The exhauster 105 includes the exhaust chamber 111, an exhaust pipe 181 provided on the side surface of the exhaust chamber 111, and an exhaust apparatus 182 connected to the exhaust pipe 181 and including a vacuum pump, a pressure control valve, and the like.

Next, the operation of the first processing apparatus 5 will be described with reference to FIG. 9 again. First, the transport apparatus 2 carries the substrate 10 into the processing container 101, places the substrate 10 on the stage 102, and cleans the surface of the substrate 10 as necessary.

Next, the pressure in the processing container 101 and the temperature of the substrate are controlled to desired values to form graphene 21. Specifically, Ar gas, which is a plasma generating gas, is supplied from the shower ring 142 to a portion directly under the microwave transmission plate 124, and microwaves generated by the microwave generator 122 are guided by the waveguide 127, the mode conversion mechanism 131, and the coaxial waveguide 128 of the microwave transmission mechanism 123 to the slow-wave material 126 to be radiated from the slow-wave material 126 into the processing container 101 via the slots 121a of the planar slot antenna 121 and the microwave transmission plate 124, thereby igniting plasma. The microwaves spread as surface waves in a region directly under the microwave transmission plate 124, and surface wave plasma is generated by the Ar gas so that the region becomes a plasma generating region. Then, at the time at which the plasma is ignited, C₂H₄ gas as a carbon-containing gas is supplied from the shower plate 141, and, if necessary, H₂ gas is supplied from the shower plate 141. These are excited and dissociated by the plasma diffused from the plasma generating region, and are supplied to the substrate 10 placed on the stage 102 below the shower plate 141. Since the substrate 10 is disposed in a region spaced apart from the plasma generating region and the plasma diffused from the plasma generating region is supplied to the substrate 10, the plasma has a low electron temperature on the substrate 10 and thus causes little damage to the substrate 10, and the plasma is turned into high-density plasma mainly composed of radicals. With such plasma, it is possible to cause the carbon-containing gas to react on the surface of the substrate, and thus it is possible to form graphene 21 having good crystallinity.

At this time, the C₂H₄ gas as the carbon-containing gas and, if necessary, H₂ gas are supplied to a location below the plasma generation region from the shower plate 141 and are dissociated by the diffused plasma. Thus, it is possible to suppress excessive dissociation of these gases. However, these gases may be supplied to the plasma generating region. In addition, Ar gas as the plasma generating gas may not be used, and, for example, C₂H₄ gas as the carbon-containing gas and H₂ gas may be supplied to the plasma generating region to directly ignite the plasma.

Next, the second processing apparatus 6 will be described with reference to FIG. 10. The second processing apparatus 6 illustrated in FIG. 10 is a plasma sputtering apparatus. The second processing apparatus 6 includes a processing container 261 formed in a tubular shape by, for example, aluminum or the like. The processing container 261 is grounded, an exhaust port 263 is provided in the bottom portion 262 thereof, and an exhaust pipe 264 is connected to the exhaust port 263. A throttle valve 265 and a vacuum pump 266 that perform pressure adjustment are connected to the exhaust pipe 264, so that the interior of the processing container 261 can be evacuated. Further, the bottom portion 262 of the processing container 261 is provided with a gas introduction port 267 for introducing a desired gas into the processing container 261. A gas supply pipe 268 is connected to the gas introduction port 267, and a gas source 269 configured to supply a rare gas as a gas for exciting plasma such as Ar gas or another necessary gas such as N₂ gas is connected to the gas supply pipe 268. A gas controller 270 including a gas flow rate controller, a valve, and the like is interposed in the gas supply pipe 268.

A placement mechanism 272 configured to place the substrate 10 thereon is provided in the processing container 261. The placement mechanism 272 includes a stage 273 formed in a disk shape, and a hollow tubular support column 274 that supports the stage 273 and is grounded. The stage 273 is made of a conductive material such as an aluminum alloy and is grounded via the support column 274. A cooling jacket 275 is provided inside the stage 273 to supply a coolant through a coolant flow path (not illustrated). In the stage 273, a resistance heater 297 coated with an insulating material is embedded on the cooling jacket 275. The resistance heater 297 is fed with power from a power supply (not illustrated). The stage 273 is provided with a thermocouple (not illustrated), and the controller 8 controls supply of the coolant to the cooling jacket 275 and feeding of power to the resistance heater 297 based on the temperature detected by the thermocouple, thereby controlling the temperature of the substrate to a desired temperature.

On the top surface side of the stage 273, a thin disk-shaped electrostatic chuck 276 configured by embedding an electrode 276b in a dielectric member 276a such as alumina is provided so that the substrate 10 can be attracted and held by an electrostatic force. The lower portion of the support column 274 penetrates an insertion hole 277 formed in the central portion of the bottom portion 262 of the processing container 261 and extends downward. The support column 274 is configured to be movable upward and downward by a lifting mechanism (not illustrated), whereby the entire placement mechanism 272 is raised and lowered.

A metal bellows 278 configured to be expandable and contractible is provided so as to surround the support column 274, wherein the upper end of the metal bellows 278 is airtightly joined to the bottom surface of the stage 273 and the lower end thereof is airtightly joined to the top surface of the bottom portion 262 of the processing container 261, so that the placement mechanism 272 can be moved upward and downward while maintaining the airtightness inside the processing container 261.

The bottom portion 262 is vertically provided with, for example, three support pins 279 (of which only two are illustrated in FIG. 10) directed upward, and a pin insertion hole 280 is provided in the stage 273 in correspondence with the support pins 279. Therefore, when the stage 273 is lowered, the substrate 10 is received at the upper ends of the support pins 279 that penetrate the pin insertion holes 280, and the substrate 10 is delivered to and from the transport apparatus 2 that enters from the outside. Therefore, on the lower side wall of the processing container 261, a carry-in/out port 281 for the substrate 10 by the transport apparatus 2 illustrated in FIG. 8 is provided, and the carry-in/out port 281 is provided with a gate valve G configured to open/close the carry-in/out port 281.

A chuck power supply 283 is connected to the electrode 276b of the above-described electrostatic chuck 276 via a power feeding line 282, and by applying a DC voltage from the chuck power supply 283 to the electrode 276b, the substrate 10 is attracted and held by an electrostatic force. In addition, a radio-frequency bias power supply 284 is connected to the power feeding line 282, and radio-frequency power for bias is supplied to the electrode 276b of the electrostatic chuck 276 via the power feeding line 282, so that bias power is applied to the substrate 10. As the frequency of the radio-frequency power, preferably 400 kHz to 60 MHz, and for example, 13.56 MHz, is adopted.

Meanwhile, on the ceiling of the processing container 261, a transmission plate 286 made of a dielectric material such as alumina, which is permeable to radio-frequency waves, is airtightly provided via a sealing member 287 such as an O-ring. Then, above the transmission plate 286, a plasma generating source 288 for plasmarizing a rare gas as a plasma excitation gas, for example, Ar gas, to generate plasma in the processing space S in the processing container 261 is provided. As the plasma excitation gas, other rare gases such as He, Ne, and Kr may be used instead of Ar.

The plasma generating source 288 includes an induction coil 290 provided to correspond to the transmission plate 286, and the induction coil 290 is connected to, for example, a radio-frequency power supply 291 of 13.56 MHz for plasma generation, and radio-frequency power is introduced into the processing space S through the above-described transmission plate 286 to form an induced electric field.

Directly below the transmission plate 286, a baffle plate 292 made of, for example, aluminum and configured to diffuse the introduced radio-frequency power is provided. Below the baffle plate 292, for example, a target 293 made of Cu or Ta forming an annular shape (a conical shell shape), the cross section of which is inclined inward to surround the lateral side of the upper portion of the processing space S, is provided, and a voltage-variable DC power supply 294 for the target, which applies DC power for attracting Ar ions, is connected to the target 293. An AC power supply may be used instead of the DC power supply 294.

On the outer peripheral side of the target 293, a magnet 295 for applying a magnetic field to the target 293 is provided. The target 293 is sputtered by Ar ions in the plasma and is mostly ionized as it passes through the plasma.

In the lower portion of the target 293, a cylindrical protective cover member 296 made of, for example, aluminum or copper is provided to surround the processing space S. The protective cover member 296 is grounded, and the lower portion thereof is bent inward and is located near the side portion of the stage 273. Therefore, the inner end of the protective cover member 296 is provided to surround the outer peripheral side of the stage 273.

Next, the operation of the second processing apparatus 6 will be described with reference to FIG. 10 again. First, the transport apparatus 2 carries the substrate 10 into the processing container 261 and places the substrate 10 on the stage 273, and the substrate 10 is attracted by the electrostatic chuck 276.

Next, the pressure inside the processing container 261 and the temperature of the substrate are controlled to desired values, so that the transition metal 22 is deposited. Specifically, the interior of the processing container 261 is maintained at a desired degree of vacuum while making Ar gas flow into the processing container 261 at a desired flow rate. Thereafter, DC power is applied to the target 293 from the DC power supply 294, and radio-frequency power (plasma power) is further supplied from the radio-frequency power supply 291 of the plasma generating source 288 to the induction coil 290. Desired radio-frequency power for bias is supplied from the radio-frequency bias power supply 284 to the electrode 276b of the electrostatic chuck 276.

As a result, argon plasma is formed in the processing container 261 by the radio-frequency power supplied to the induction coil 290, and argon ions are generated. These ions are attracted to the DC voltage applied to the target 293 and collide with the target 293, and the target 293 is sputtered to emit particles. The controller 8 controls the DC voltage applied to the target 293 to control the amount of emitted particles.

Most of the particles sputtered from the target 293 are ionized while passing through the plasma. Here, the particles emitted from the target 293 are in a state in which ionized particles and electrically neutral atoms are mixed, and are scattered downward. In particular, it is possible to ionize the particles with high efficiency by increasing the pressure in the processing container 261 to some extent and thereby increasing the plasma density. The ionization rate at this time is controlled by the radio-frequency power supplied from the radio-frequency power supply 291.

Then, when ions enter the region of an ion sheath having a thickness of about several mm formed on the surface of the substrate 10 by the radio-frequency power for bias applied from the radio-frequency bias power supply 284 to the electrode 276b of the electrostatic chuck 276, the ions are attracted to the substrate 10 to be accelerated with strong directivity and are deposited on the substrate 10. As a result, deposition of transition metal 22 is performed.

Although the embodiments of the film forming method and the film forming system according to the present disclosure have been described above, the present disclosure is not limited to the above-described embodiments or the like. Various changes, modifications, substitutions, additions, deletions, and combinations can be made within the scope of the claims. Of course, these also fall within the technical scope of the present disclosure.

This application claims priority based on Japanese Patent Application No. 2019-233149 filed with the Japan Patent Office on Dec. 24, 2019, and the entire disclosure of Japanese Patent Application No. 2019-233149 is incorporated herein in its entirety by reference.

### EXPLANATION OF REFERENCE NUMERALS

10: substrate, 11: base substrate, 12: first conductive film, 20: composite layer, 21: graphene, 22: transition metal

1. A film forming method comprising:
preparing a substrate that includes a base substrate and a first conductive film that is formed on the base substrate;
forming, on the first conductive film, a composite layer that includes layers of graphene and includes, as dopant atoms, a transition metal from 4^{th} period to 6^{th} period in a periodic table, excluding lanthanoids, between the layers of graphene; and
forming, on the composite layer, a second conductive film which is electrically connected to the first conductive film via the composite layer.

2. The film forming method of claim 1, wherein the transition metal has an open-shell d-orbital, and has 1 or more and 9 or less d-electrons in the open-shell d-orbital.

3. The film forming method of claim 2, wherein the transition metal is V, Rh, Ti, Mo, or W.

4. The film forming method of claim 3, wherein the composite layer contains the transition metal between the graphene closest to the first conductive film and the first conductive film.

5. The film forming method of claim 4, wherein the composite layer contains the transition metal between the graphene closest to the second conductive film and the second conductive film.

6. The film forming method of claim 5, wherein the first conductive film is a metal film containing Cu, W, Mo, Co, or Ru, or a semiconductor film containing a dopant.

7. The film forming method of claim 6, wherein the forming the composite layer alternately includes forming the graphene in one or more layers and three or fewer layers and depositing the transition metal.

8. The film forming method of claim 7, wherein the substrate includes an insulating film formed on the first conductive film and a recess that penetrates the insulating film to expose the first conductive film,
the composite layer is formed on a bottom surface and a side surface of the recess, and
the second conductive film is filled in the recess.

9.
The film forming method of claim 1, wherein the composite layer contains the transition metal between the graphene closest to the first conductive film and the first conductive film.

10. The film forming method of claim 1, wherein the composite layer contains the transition metal between the graphene closest to the second conductive film and the second conductive film.

11. The film forming method of claim 1, wherein the first conductive film is a metal film containing Cu, W, Mo, Co, or Ru, or a semiconductor film containing a dopant.

12. The film forming method of claim 1, wherein the forming the composite layer alternately includes forming the graphene in one or more layers and three or fewer layers and depositing the transition metal.

13. The film forming method of claim 1, wherein the substrate includes an insulating film formed on the first conductive film and a recess that penetrates the insulating film to expose the first conductive film,
the composite layer is formed on a bottom surface and a side surface of the recess, and
the second conductive film is filled in the recess.

14. A film forming system comprising:
a transport apparatus configured to transport a substrate including a base substrate and a first conductive film formed on the base substrate;
an interface apparatus that forms a vacuum chamber that accommodates the transport apparatus;
a first processing apparatus located adjacent to the interface apparatus and configured to form, on the first conductive film, graphene in one or more layers and three or fewer layers;
a second processing apparatus located adjacent to the interface apparatus and configured to deposit a transition metal from 4^{th} period to 6^{th} period in a periodic table, excluding lanthanoids, as dopant atoms on the graphene;
a third processing apparatus located adjacent to the interface apparatus and configured to form, on a composite layer that includes layers of graphene and includes, as dopant atoms, the transition metal between the layers of graphene, a second conductive film that is electrically connected to the first conductive film via the composite layer; and
a controller configured to control the transport apparatus, the first processing apparatus, the second processing apparatus, and the third processing apparatus to form the composite layer and the second conductive film.
